(19) United States
(12) Patent Application Publication
(10) Pub. No.: US 2008/0197015 A1
(43) Pub. Date: Aug. 21, 2008

(54) MULTIPLE-MAGNETRON SPUTTERING SOURCE WITH PLASMA CONFINEMENT

(76) Inventors: TERRY BLUCK, Santa Clara, CA (US); Patrick R. Ward, San Jose, CA (US)

Correspondence Address: NIXON PEABODY, LLP, 401 9TH STREET, NW, SUITE 900, WASHINGTON, DC, 20004-2128, US

(21) Appl. No.: 11/958,217

(22) Filed: Dec. 17, 2007

Related U.S. Application Data
(60) Provisional application No. 60/890,243, filed on Feb. 16, 2007.

(51) Int. Cl. C23C 14/35

(52) U.S. Cl. 204/192.12; 204/298.17; 204/298.11

(57) ABSTRACT

A sputtering source has a magnetron and a target. Control magnets are provided about the target to modify the magnetic lines of the magnetron. A sputtering source has several magnetrons, each having a respective target. A plasma/sputtering shield is provided in front of the targets. The shield has several windows, each aligned with one of the targets. Magnets are provided on the shield to control the magnetic lines of the magnetrons.

### CROSS-REFERENCE TO RELATED APPLICATIONS

This Application claims priority from U.S. Provisional Application, Ser. No. 60/890,243, filed Feb. 16, 2007, which is incorporated herein by reference in its entirety.

### BACKGROUND

1. Field of the Invention

The general field of the invention relates to sputtering technology and, more specifically, to a unique sputtering source having enhanced plasma confinement.

2. Related Arts

Sputtering technology is well known in the art and is used for, among others, thin layer formation. This technology is used in, for example, semiconductor fabrication and hard disk fabrication. An example of a system utilizing sputtering chambers for hard disk fabrication is disclosed in U.S. Pat. No. 6,919,001, to Fairbaim et al. In such systems, the material to be deposited on a substrate is provided in the form of a target, and a magnetron is used to sputter the target material onto the substrate. In some systems the substrate is moved, while in others it is stationary.

FIG. 1 illustrates a conventional sputtering chamber using a magnetron. In FIG. 1, a vaccum chamber 100 has a substrate holder 105 which holds the substrate 110. In this particular example the substrate holder 105 is stationary, but in other configurations it may be movable for scanning the substrate 110 in front of the target assembly 125. The target assembly may be constructed from a target material, 130, and a backing plate bonded to the target material or the target materail may be mounted directly to the magnetron. The purpose of the backing plate is to provide strength to the target assembly for brittle or thin targets. Magnetron 115 includes magnets 120, situated behind the target 125. The target 125 has a layer of sputtering material 130 facing the substrate 110. The use of magnets 120 in magnetron 115 helps trapping secondary electrons in the plasma close to the target. The electrons follow helical paths around the magnetic field lines 135, thereby undergoing more ionizing collisions with plasma species near the target. This enhances the ionization of the plasma near the target, leading to a higher sputtering rate.

However, when the target material 130 has magnetic permeability, such as cobalt or iron, it is difficult to control the magnetic lines. Magnetic lines that emanate and terminate at the front faces of the magnets 120 may follow the path within the sputtering material 130, shown by the broken-line curves 137 in FIG. 1. The lines do not contribute to plasma species ionization, as they do not exit the target. On the other hand, magnetic lines that emanate from the side faces extend beyond the sides of the target, as shown by solid curves 135. Consequently, plasma confinement becomes difficult, especially when the target is small. That is, it is difficult to confine the plasma to a small area in front of the target. The greater the permeability the more difficult it is to confine the plasma over the target.

With the advancement of technology, multiple layers of increasingly thin dimensions are sometimes needed to be deposited, especially in electronic technology, such as semiconductor devices and magnetic disks. Consequently, the substrates need to be sequentially exposed to several targets of different materials to form a “stack” of layers of different materials. For example, in modern recordable media, such as hard disks, interlaced layers of platinum and cobalt are deposited to form the magnetic recordable media. Each of these layers may be increasingly thin, for example, in the order of 5-20 angstrom. This is especially the case for newer perpendicular recording technology for hard disks. As a result, the substrate may need to be repeatedly cycled through different sputtering chambers, so as to deposit the stack of materials, sometimes consisting of up to 50 different layers.

Therefore, a system is needed that will enable better control over the plasma confinement so as to enhance the deposition rate. Furthermore, a system is needed that will enable faster deposition of multiple layers to reduce the cycling of substrates in many sputtering chambers.

According to aspects of the invention, a sputtering source is provided, comprising: a housing; a magnetron situated within the housing, the magnetron having at least one magnet; a sputtering target mounted in front of the magnetron, the sputtering target having a puttering face; and a control magnet arrangement situated about the sputtering face so as to control magnetic lines emanating from the at least one magnet of the magnetron. The control magnet arrangement may be situated about the sputtering target so as to push magnetic lines into the target. The control magnet arrangement may be situated about the sputtering target so as to pull magnetic lines from the sputtering face of the target. The sputtering source may further comprise a shield situated about the sputtering face of the target. The control magnet arrangement may be mounted onto the shield. The control magnet arrangement may be incorporated inside the shield. The sputtering source may further comprise: at least one additional magnetron; at least one additional target; and a shield having a plurality of windows, each aligned with one target. The control magnet arrangement may be situated about the shield. The control magnet arrangement may be incorporated into the shield.

According to aspects of the invention, a sputtering system is provided, comprising a plurality of processing chambers, at least one of the processing chambers comprises: a processing cavity; tracks for transporting a substrate carrier; a sputtering source, the sputtering source comprising: a housing; a plurality of magnetrons situated within the housing; a plurality of sputtering targets, each mounted onto a respective sputtering source; and a sputtering shield having a plurality of windows, each window aligned with a respective sputtering target. The system may further comprise a plurality of control magnets situated about the shield. The plurality of control magnets may be incorporated into the shield. The system may further comprise: a second sputtering source in a facing relationship to the sputtering source. The second sputtering source may comprise: a housing; a plurality of magnetrons situated within the housing; a plurality of sputtering targets, each mounted onto a respective sputtering source; a sputtering shield having a plurality of windows, each window aligned with a respective sputtering target. The system may further comprise a plurality of control magnets situated inside the sputtering shield of the second sputtering source.

According to aspects of the invention, a method for controlling plasma confinement in a sputtering chamber is provided, comprising: evacuating the sputtering chamber; injecting plasma precursor gas into the chamber; energizing a sputtering magnetron within the chamber, the sputtering magnetron having a sputtering target and a plurality of magnets situated behind the target and generating magnetic field defined by magnetic lines; providing a plurality of control magnets about the target so as to modify the path of the magnetic lines. The method may further comprise placing a shield in front of the target. The method may further comprise mounting the control magnets onto the shield. The method may further comprise mounting the control magnets inside the shield.

### SUMMARY

The following summary of the invention is provided in order to provide a basic understanding of some aspects and features of the invention. This summary is not an extensive overview of the invention, and as such it is not intended to particularly identify key or critical elements of the invention, or to delineate the scope of the invention. Its sole purpose is to present some concepts of the invention in a simplified form as a prelude to the more detailed description that is presented below.

Embodiments of the present invention provide a system that enhances control over the plasma confinement. Embodiments of the present invention also provide a system that reduces cycling of substrates in sputtering chambers.

In one aspect of the invention, plasma confinement is improved by using a conductive shield. In a further aspect of the invention, plasma confinement is further improved by incorporating magnets in the conductive shield.

In one aspect of the invention, the number of sputtering chambers is reduced by having multiple-materials targets in each chamber.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1illustrates a sputtering chamber according to the prior art.

FIG. 2 is a conceptual diagram showing a magnetron having enhanced plasma confinement according to an embodiment of the invention.

FIG. 3 is a conceptual diagram showing a magnetron having enhanced plasma confinement according to an embodiment of the invention.

FIG. 4 is a conceptual diagram showing a magnetron having enhanced plasma confinement according to an embodiment of the invention.

FIG. 5 illustrates a magnetron having enhanced plasma confinement according to an embodiment of the invention.

FIG. 6 illustrates the arrangement of magnets 650 around or inside the shield 645.

FIG. 7 illustrates part of a pass-by system according to an embodiment of the invention.

FIG. 8 illustrates a cross-section of chamber 710.

FIG. 9 illustrates a cross section of a sputtering source according to an embodiment of the invention.

FIG. 10 is a perspective view of a multiple-target sputtering source 1000 according to an embodiment of the invention.

FIG. 11 illustrates a shield that may be used for the embodiment of FIG. 10.

FIG. 12 illustrates a cross section of a process module according to an embodiment of the invention.

FIG. 13 illustrates a chamber having three sources, each having three magnetrons, according to embodiment of the invention.

### DETAILED DESCRIPTION

Various embodiments of the invention are generally directed to a system for sputtering layers of different materials on a substrate, such as a magnetic recordable media. The system may employ several sputtering chambers, each having a sputtering magnetron arrangement for several targets, or targets having several different materials. A metallic shield is provided between the target and the substrate. Magnets may be incorporated into the shield to assist in controlling the plasma confinement.

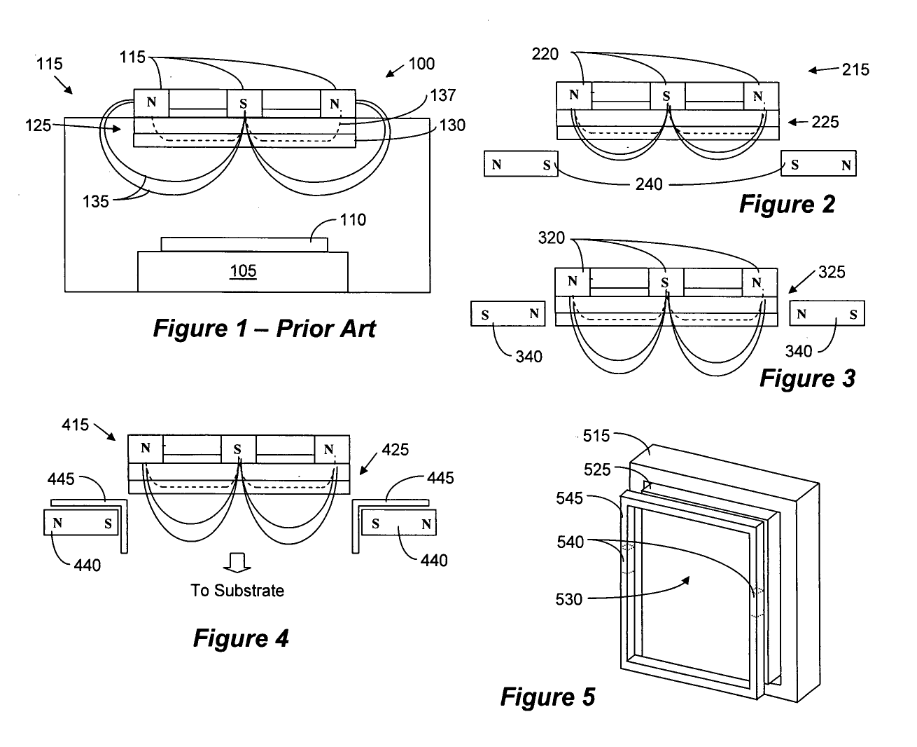

FIG. 2 is a conceptual diagram showing a magnetron having enhanced plasma confinement according to an embodiment of the invention. In the embodiment of FIG. 2, the same magnetron 215 as shown in FIG. 1 is used. However, magnets 240 have been added at a location extending beyond the front face of the target 225. In this configuration the poles of the magnets 240 are arranged so as to “pull” the magnetic lines at the outer periphery of the target, so as to cause the lines to assume a path inside, or close to the target. At the same time, the magnets 240 push on the lines that are at the center of the target, so as to keep all of the lines traversing the space at the front of the target to remain very close to the target.

In the particular example of FIG. 2, magnets 220 are arranged so that the north poles are at the sides of the target, while the south poles are at the center of the target. In such a configuration, magnets 240 should be placed so that their south poles are close to the target and the north poles point away from the target. In this way, the south poles of magnets 240 attract the magnetic lines emanating from the north poles of magnets 220, while repelling the magnetic lines towards the south poles of magnets 220, i.e., towards the center of the target 225. In this manner, the plasma is confined to the area just in front of the target, and does not extend beyond the sides of the target, as is the case with the arrangement of FIG. 1.

FIG. 3 is a conceptual diagram showing a magnetron having enhanced plasma confinement according to an embodiment of the invention. In the embodiment of FIG. 3, the same magnetron 315 as shown in FIG. 1 is used. However, magnets 340 have been added at or behind the front sputtering face of the target 325. In this configuration the poles of the magnets 340 are arranged so as to “push” the magnetic lines at the outer periphery of the target, so as to cause the lines to assume a path inside, or close to the target. By pushing the magnetic lines into the target, the target is saturated and the magnetic lines “pop out” from the face of the target, as shown in FIG. 3.

In the particular example of FIG. 3, magnets 320 are arranged so that the north poles are at the sides of the target, while the south poles are at the center of the target. In such a configuration, magnets 340 should be placed so that their north poles are close to the target and the south poles point away from the target. In this way, the north poles of magnets 320 repel the magnetic lines towards the sides of the target 325. In this manner, the plasma is confined to the area just in front of the target, and does not extend beyond the sides of the target, as is the case with the arrangement of FIG. 1.

FIG. 4 is a conceptual diagram showing a magnetron having enhanced plasma confinement according to an embodiment of the invention. In the embodiment of FIG. 4, the same magnetron 415 as shown in FIG. 1 is used. However, a plasma/sputtering shield 445 is placed in front of the sputtering face of target 425. In this embodiment the plasma/sputtering shield is made of conductive material, however, non-conductive material may also be used. Additionally, in this embodiment, magnets 440 have been added at or behind the face of the shield 445 which face target 425. By placing the plasma shield 445 and the magnets 440 in front of the target, enhanced plasma confinement is achieved. Additionally, enhanced control over species-sputtering is achieved, as the shield prevents sputtered species from reaching beyond the sides of the target.

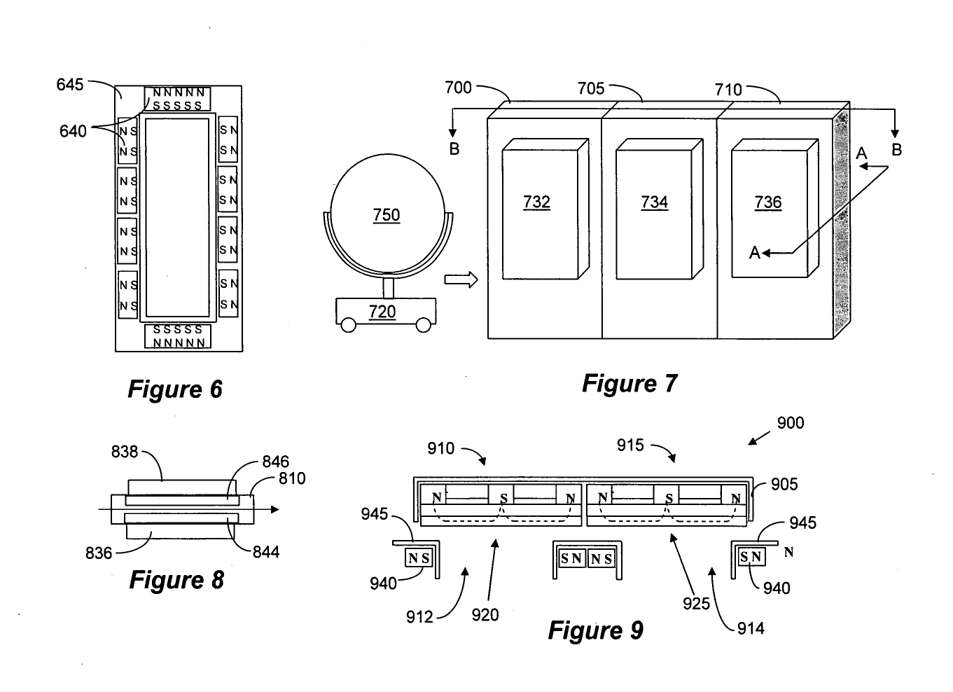

FIG. 5 illustrates a magnetron having enhanced plasma confinement according to an embodiment of the invention, implementing the concept illustrated in FIG. 4. In the embodiment of FIG. 5, magnetron 515 has a target 525 mounted thereto. A plasma/sputtering shield 545 is placed in front of the target 525, facing the sputtering face 530 of target 525. In this embodiment, magnets 540 are placed inside the shield 545, as illustrated by the broken line. FIG. 6 illustrates the arrangement of magnets 640 around or inside the shield 645. Such an arrangement may be used in the embodiment of FIG. 5.

FIG. 7 illustrates part of a pass-by system according to an embodiment of the invention, which is beneficial for sputtering consecutive layers of different materials on a substrate. The system in this example is particularly suitable for fabricating recording media, such as recording magnetic disks, which require many alternating layers of different materials sputtered on both sides of the substrate. In this particular example, only 3 chambers are shown, but this arrangement may be repeated to form any number of chambers, as illustrated by the above-cited '001 patent.

In the embodiment of FIG. 7, each of chambers 700, 705 and 710 may be constructed generally similarly to the chambers shown in the '001 patent. That is, each chamber has means for evacuating its processing section, means for transporting substrate carrier 720, and two sputtering sources on each side. In FIG. 7 only one sputter source, 732, 734 and 736, is shown for each chamber, as the other sputter source is on the other side, which is not visible in this perspective. Each sputter source has sputtering target of a given material, such that by selecting the proper targets and having the substrate carrier moving serially from chamber to chamber, layers of different materials may be sputtered on the substrate 750. For example, target 732 may have platinum, target 734 cobalt, and target 736 platinum, to thereby sputter alternating layers of platinum, cobalt, platinum, . . . , on the substrate.

FIG. 8 illustrates a cross-section along lines A-A of chamber 710. As shown in FIG. 8, the chamber 810 has two sputtering sources 836 and 838. Each of the sputtering sources is constructed similar to the embodiment shown in FIG. 5, so that each sputter source has a shield, 844, 846, and magnets (not shown) situated in the shields. The substrate moves along the path shown by the arrow. When the substrate is inside the chamber, the substrate holder may either stop until sputtering is completed, or continue move so as to scan the substrate in front of the sputtering sources. The substrate is placed very close to the shields, so that the sputtering species are contained to only within the window of the shield.

While the embodiment depicted in FIG. 7 is effective in sputtering alternating layers on a substrate, as noted above perpendicular recording technology requires many more layers than conventional parallel recording technology. On the other hand, the layers of perpendicular recording technology are very thin, thereby requiring short sputtering time. FIG. 9 illustrates a cross section of a sputtering source according to an embodiment of the invention, having multiple targets for discrete sputtering of separate layers.

In FIG. 9, a sputtering source has a housing 905, within which two magnetrons 910, 915 are situated. Each of magnetrons 910, 915, has a target 920, 925, respectively, mounted thereupon. The targets may be of same or different sputter material. A plasma/sputtering shield 945 is provided, which has two windows 912, 914, aligned with one of the targets 920, 925, respectively. In this embodiment, magnets 940 are also provide at or within the shield 945; however, in other embodiments the magnets may be omitted.

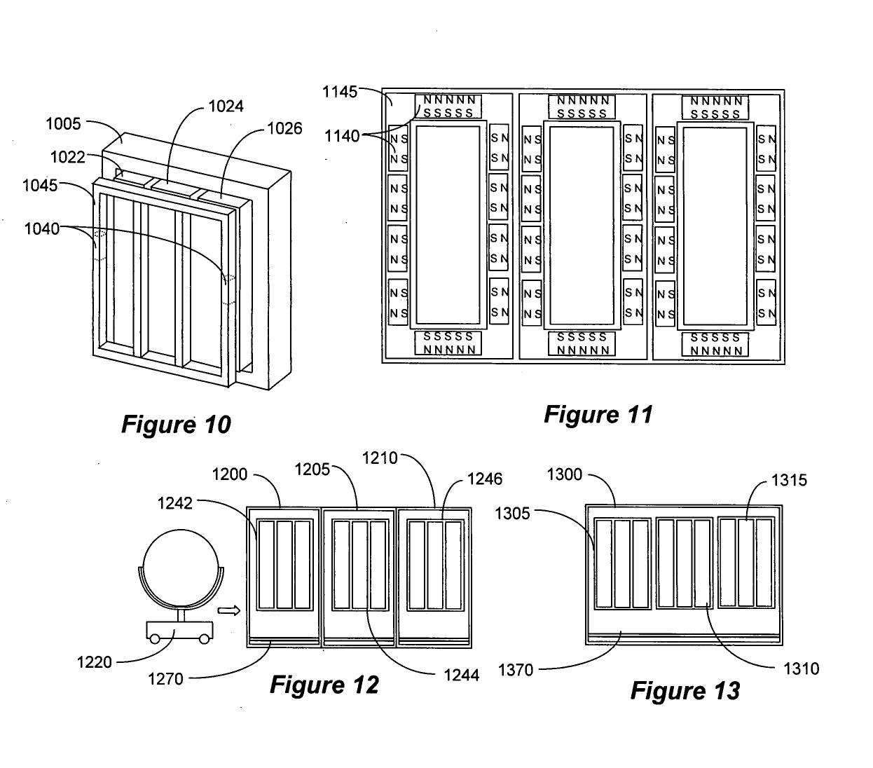

FIG. 10 is a perspective view of a multiple-target sputtering source 1000 according to an embodiment of the invention. The sputtering source of FIG. 10 is somewhat similar to that illustrated in FIG. 9, except that three magnetrons and three sputtering targets are provided within the single source 1000. As shown, the source's housing 1005 houses three targets, 1022, 1024, and 1026. The magnetrons driving these targets are not visible in this perspective. A shield 1045 is provided in front of the sputtering face of the targets. The shield 1045 has three windows, each aligned with one of the sputtering targets.

When a multiple-target sputtering source, such as source 1000, is installed in a sputtering chamber, such as any of chambers 700, 705, 710, of FIG. 7, three layers may be sputtered onto the substrate in one pass. Depending on the sputtering requirement, the targets may be of the same or of different sputtering material. For example, when using the system with a substrate carrier that is moving during sputtering, it is beneficial that the speed of the carrier be constant. Consequently, it is required that each process step be performed at the same amount of time as any other steps. The process time may therefore be controlled by determining the target's sputtering material. For example, if one wishes to sputter 5 angstrom of platinum and then 10 angstrom of cobalt, then one may use source 1000 with target 1022 being of platinum while targets 1024 and 1026 being of cobalt to achieve a similar target lifetime. In this way, when the carrier moves at constant speed, the layer of cobalt sputtered on the substrate may be twice as thick as that of platinum with each target processing the same amount of substrates over the target life. Each target can be powered by its own power supply so by controlling the power on each target the deposited film thickness can be controlled. On the other hand, if one wishes to have alternating layers of platinum and cobalt of the same thickness, then targets 1022 and 1026 would be of platinum, while target 1024 of cobalt.

While in FIG. 10 no magnets are shown with or inside the shield 1045, as with prior embodiments, the magnets may be incorporated inside the shield 1045. FIG. 11 illustrates a shield that may be used for the embodiment of FIG. 10. The shield 1145 has multiple windows, each aligned in front of one sputtering target, and incorporates magnets situated around each window. The shield may be constructed of a metallic material and the magnets may be enclosed inside the shield's frame. The windows of the shields enable accurate control of the plasma and of sputtered material. When the substrate is passed next to the shield, each target's sputtered material is confined to within the opening of the window, so that there is no cross-sputtering of the different material. Additionally, when magnets are placed within the shield, the plasma of each magnetron is confined within the window and no cross-talk of plasmas from different magnetrons occurs.

FIG. 12 illustrates a cross section of a process module according to an embodiment of the invention. The illustration of FIG. 12 is similar to a cross-section along lines B-B of FIG. 7, except that the chambers 1200, 1205 and 1210, employ the multiple-magnetron sputtering source of FIG. 10. In FIG. 12, three shields, 1242, 1244 and 1246 are used, each in front of a respective multiple magnetron sputtering source. Since the sputtering source has three magnetrons with three targets, each shield has three windows aligned with the targets. As can be appreciated, as many chambers as needed may be arranged in a single or multiple lines, just as shown in the '001 patent. The carrier 1220 may be transported on tracks 1270 at constant speed during sputtering, so that multiple layers are sputtered on the substrate. Moreover, each chamber may have more than one multiple-magnetron sputtering source. For example, FIG. 13 illustrates a chamber 1300 having three sources, 1305, 1310, and 1315, each having three magnetrons. Tracks 1370 are provided for carrier transport, so that the substrate is scanned across all nine targets and get coated with 9 layers of same or different materials.

It should be understood that processes and techniques described herein are not inherently related to any particular apparatus and may be implemented by any suitable combination of components. Further, various types of general purpose devices may be used in accordance with the teachings described herein. It may also prove advantageous to construct specialized apparatus to perform the method steps described herein. The present invention has been described in relation to particular examples, which are intended in all respects to be illustrative rather than restrictive. Those skilled in the art will appreciate that many different combinations of hardware, software, and firmware will be suitable for practicing the present invention. For example, the described software may be implemented in a wide variety of programming or scripting languages, such as Assembler, C/C++, perl, shell, PHP, Java, HFSS, CST, EEKO, etc.

The present invention has been described in relation to particular examples, which are intended in all respects to be illustrative rather than restrictive. Those skilled in the art will appreciate that many different combinations of hardware, software, and firmware will be suitable for practicing the present invention. Moreover, other implementations of the invention will be apparent to those skilled in the art from consideration of the specification and practice of the invention disclosed herein. It is intended that the specification and examples be considered as exemplary only, with a true scope and spirit of the invention being indicated by the following claims.

1. A sputtering source, comprising,
a housing;
a magnetron situated within the housing, the magnetron having at least one magnet;
a sputtering target mounted in front of the magnetron, the sputtering target having a puttering face;
a control magnet arrangement situated about the sputtering face so as to control magnetic lines emanating from the at least one magnet of the magnetron.

2. The sputtering source of claim 1, wherein the control magnet arrangement is situated about the sputtering target so as to push magnetic lines into the target.

3. The sputtering source of claim 1, wherein the control magnet arrangement is situated about the sputtering target so as to pull magnetic lines from the sputtering face of the target.

4. The sputtering source of claim 1, further comprising a shield situated about the sputtering face of the target.

5. The sputtering source of claim 4, wherein the control magnet arrangement is mounted onto the shield.

6. The sputtering source of claim 4, wherein the control magnet arrangement is incorporated inside the shield.

7. The sputtering source of claim 1, further comprising:
at least one additional magnetron;
at least one additional target; and
a shield having a plurality of windows, each aligned with one target.

8. The sputtering source of claim 7, wherein the control magnet arrangement is situated about the shield.

9. The sputtering target of claim 7, wherein the control magnet arrangement is incorporated into the shield.

10. A sputtering system comprising a plurality of processing chambers, at least one of the processing chambers, comprising:
a processing cavity;
tracks for transporting a substrate carrier;
a sputtering source, the sputtering source comprising:
a housing;
a plurality of magnetrons situated within the housing;
a plurality of sputtering targets, each mounted onto a respective sputtering source;
a sputtering shield having a plurality of windows, each window aligned with a respective sputtering target.

11. The system of claim 10, further comprising a plurality of control magnets situated about the shield.

12. The system of claim 11, wherein the plurality of control magnets are incorporated into the shield.

13. The system of claim 10, further comprising:
a second sputtering source in a facing relationship to the sputtering source.

14. The system of claim 13, wherein the second sputtering source comprises:
a housing;
a plurality of magnetrons situated within the housing;
a plurality of sputtering targets, each mounted onto a respective sputtering source;
a sputtering shield having a plurality of windows, each window aligned with a respective sputtering target.

15. The system of claim 14, further comprising a plurality of control magnets situated inside the sputtering shield of the second sputtering source.

16. A method for controlling plasma confinement in a sputtering chamber, comprising:
evacuating the sputtering chamber;
injecting plasma precursor gas into the chamber;
energizing a sputtering magnetron within the chamber, the sputtering magnetron having a sputtering target and a plurality of magnets situated behind the target and generating magnetic field defined by magnetic lines;
providing a plurality of control magnets about the target so as to modify the path of the magnetic lines.

17. The method of claim 16, further comprising placing a shield in front of the target.

18. The method of claim 17, further comprising mounting the control magnets onto the shield.

19. The method of claim 17, further comprising mounting the control magnets inside the shield.
